(19) United States
(12) Patent Application Publication
(10) Pub. No.: US 2015/0225230 A1
(43) Pub. Date: Aug. 13, 2015

(54) SUPPORT FOR MEMS COVER

(71) Applicant: Infineon Technologies Dresden GmbH, Dresden (DE)

(72) Inventor: Thomas SANTA, Seeboden (AT)

(73) Assignee: Infineon Technologies Dresden GmbH, Dresden (DE)

(21) Appl. No.: 14/175,970

(22) Filed: Feb. 7, 2014

(51) Int. Cl. B81B 7/00; B81C 1/00

(52) U.S. Cl. CPC B81B 7/0058; B81C 1/00666

(57) ABSTRACT

Embodiments related to a MEMS device in which a support structure for supporting a cover is formed in a cavity are described and depicted.

### BACKGROUND

MEMS (Micro Electrical Mechanical System) devices are used in more and more applications and systems nowadays. MEMS devices include for example MEMS oscillators, MEMS accelerometers etc. MEMS devices are encapsulated in cavities to protect the moving MEMS element from external influences such as air, moisture etc.

### SUMMARY

According to one aspect, a MEMS structure is arranged within a sealed cavity. A support structure is arranged within the cavity, the support structure being laterally elongated and extending in a vertical direction from a bottom of the cavity to a top of the cavity.

According to one aspect, a MEMS device comprises a cavity with top, bottom and side walls wherein a MEMS structure is provided to be movable within the cavity. The MEMS device further comprises a support structure, wherein the support structure is spaced apart from the MEMS structure and laterally surrounded by the MEMS structure.

According to one aspect, a method of manufacturing a MEMS device comprises the removing of material of a substrate such that a MEMS structure and a support structure with a laterally elongated shape are formed and the forming of a cover such that the support structure provides mechanical support for the cover.

### BRIEF DESCRIPTION OF THE SEVERAL VIEWS OF THE DRAWINGS

FIG. 1A shows a cross-sectional top view in accordance with an embodiment;

FIG. 1B shows a cross-sectional side view in accordance with an embodiment;

FIG. 2A shows a cross-sectional top view in accordance with an embodiment;

FIG. 2B shows a cross-sectional side view a cross-sectional side view in accordance with an embodiment;

FIG. 3 shows a flow diagram according to an embodiment.

### DETAILED DESCRIPTION

The following detailed description explains exemplary embodiments. The description is not to be taken in a limiting sense, but is made only for the purpose of illustrating the general principles of embodiments while the scope of protection is only determined by the appended claims.

It is to be understood that the features of the various exemplary embodiments described herein may be combined with each other, unless specifically noted otherwise.

In the various figures, identical or similar entities, modules, devices etc. may have assigned the same reference number. Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions are exaggerated for clarity.

In the described embodiments, various specific views or schematic views of elements, devices, features, etc. are shown and described for a better understanding of embodiments. It is to be understood that such views may not be drawn to scale. Furthermore, such embodiments may not show all features, elements etc. contained in one or more figures with a same scale, i.e. some features, elements etc. may be shown oversized such that in a same figure some features, elements, etc. are shown with an increased or decreased scale compared to other features, elements etc.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

Embodiments described herein are directed to a new support concept in MEMS devices. Typically, MEMS devices include MEMS structures of micro-size or nano-size which are formed in or on a substrate such as a semiconductor chip. Such MEMS structures may be covered with a cover to encapsulate the MEMS structures in order to prevent the intrusion of dirt, humidity etc which may degrade or destroy the operation of the MEMS device. Some embodiments described herein provide a new concept for a cover to encapsulate a MEMS structure in which the cover is mechanically supported by an intermediate support structure of lateral elongated shape. Some embodiments described herein provide a support structure to support a cover wherein the support structure is laterally completely surrounded by a movable MEMS structure in a spaced apart relationship to the movable MEMS structure.

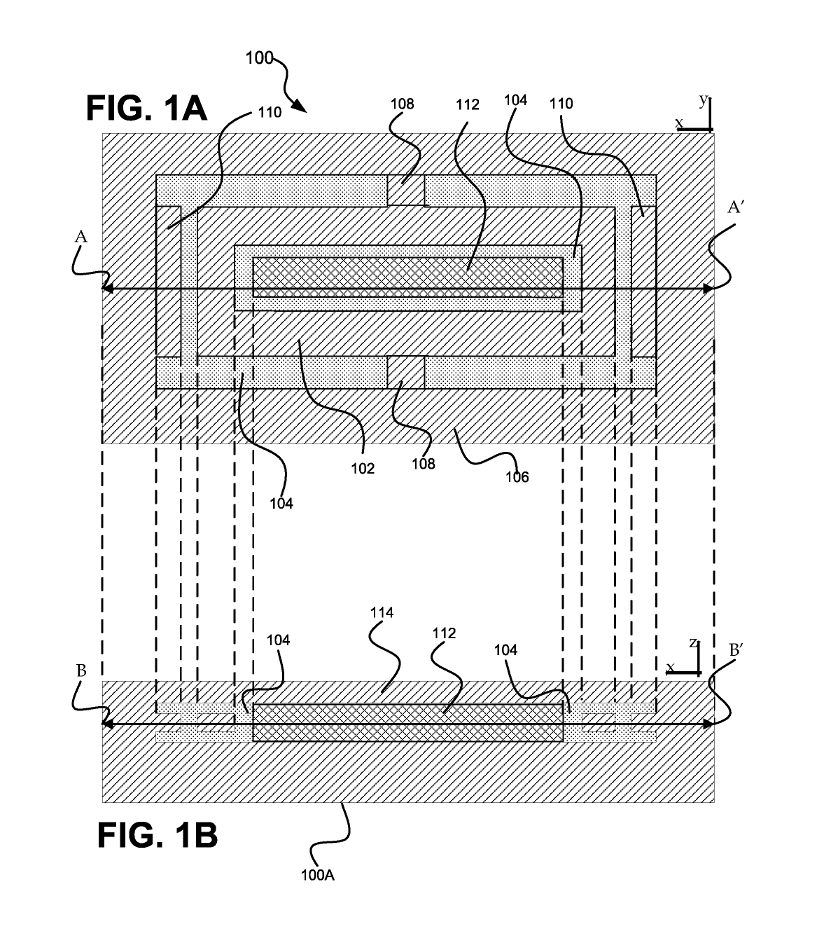

FIG. 1A shows a schematic cross sectional view from a top of a MEMS device 100 including a MEMS structure 102 formed in a cavity 104. FIG. 1B shows a schematic cross-sectional view from a side of the device 100 along a line A-A′ shown in FIG. 1A. Line B-B′ in FIG. 1B indicates the level at which the cross-sectional view from top is shown in FIG. 1A. As can be seen from FIG. 1A, the cavity 104 is laterally bound by sidewall portions 106. The side wall portions 106 laterally completely surround the cavity 104. The side wall portions form in embodiments a wall to provide a lateral closure of the cavity. In some embodiments, the MEMS structure 102 and the side wall portions 106 are formed of the same material. In some embodiments, the MEMS structure 102 and the material of the sidewall portions 106 are formed of semiconductor material. The side wall portions 106 may in some embodiments be an integral part of a substrate. The side wall portions 106 and MEMS structure 102 may in some embodiments be formed from the same substrate, e.g. by etching structures in the substrate.

The MEMS structure 102 is provided freely movable compared for example to the non-movable side wall portions 106. In the embodiment of FIGS. 1A and 1B, the MEMS structure 102 is suspended by anchor portions 108 which mechanically connect the MEMS structure 102 to side wall portions 106. In the embodiment of FIGS. 1A and 1B, the anchor portions 108 are mechanically connected to the sidewall portions 106 on two op-posing sides of the MEMS structure 102. However other structures, other arrangements or other anchor points may be provided for allowing the MEMS structure 102 to be movable. For example, spring-type structures or other flexible structures may be used for providing the MEMS structure 102 movable.

Electrode portions 110 are provided on two lateral sides for generating resonating oscillation for the MEMS structure 102. The MEMS device 100 may in some embodiments be a resonator device for providing clocking signals sometimes referred to as a silicon clock resonator. The MEMS structure 102 may therefore in some embodiments comprise a flexible resonating element. The MEMS structure 102 may for example comprise a flexible beam of a piezo-resistive Free-Free-Beam resonator.

The MEMS structure 102 may include a flexural beam which is electro-statically coupled to two symmetrical electrodes, wherein one of the symmetrical electrodes is used to drive the beam into resonance and the other one is used to collect the output signal. In some embodiments, a free-free condition resonating operation is provided by suspending the resonating beam of the MEMS structure 102 at the anchor points 108 which are joined to a resonating beam in two points which correspond to the nodes of the free-free mode to be excited in the MEMS structure 102. The length of the anchor beams connected with the resonating MEMS structure 102 may in some embodiments be designed to resonate on a second clamped-clamped mode at the same frequency of the MEMS structure. In some embodiments, the anchor beams may not exert a bending moment on the resonating MEMS structure, so that the MEMS structure 102 is minimally affected by the anchor beams. Thus, the MEMS structure 102 can be provided decoupled from the anchor points.

In some embodiments, the MEMS structure 102 is driven by the electrodes 110 to oscillate in resonance. In some embodiments, an electric feedback loop is provided to allow the MEMS structure 102 to oscillate. The electrodes are mechanically connected or formed integrally with the side wall portions 106 but are electrically insulated from the side wall portions 106. In some embodiments, the MEMS structure 102 oscillates with a frequency above 1 MHz. In some embodiments, the MEMS structure 102 oscillates with a frequency above 20 MHz. In some embodiments, the MEMS structure oscillates with a frequency above 50 MHz.

The operation of the MEMS structure 102 at high frequencies is provided in embodiments at an air pressure much lower than atmospheric pressure or substantially at vacuum. For example, according to some embodiments, the air pressure in the cavity may be 1% of the ambient air pressure or lower. According to some embodiments, the air pressure may be below 5×10² Pascal (compared to an ambient atmosphere of about 10⁵ Pascal). In some embodiments the air pressure may be below 102 Pascal. The low air pressure in the cavity reduces adverse air effects which increase with increasing oscillation frequency.

Within the cavity 104, a support structure 112 is provided for mechanically supporting a cover 114 shown in FIG. 1 B. In some embodiments, the support structure 112 may be a freestanding wall to mechanically support the cover 114. While a freestanding wall is is not mechanically connected to the side wall portions 106 other embodiments may include a support wall which is mechanically connected to the side wall portions 106 by thin structures such as a fin or a bar. In some embodiments, the side wall portions 106 may be mechanically connected to central parts of the support wall. The cover 114 is provided to cover and hermetically seal the MEMS structure 102. The cover 114 may be formed as a layer above or integrated in the semiconductor substrate in order to provide a chip-level seal for the MEMS structure 102. The cover 112 may have conductive structures penetrating the cover in order to supply allow electrical signals to and from electrodes or terminals of the MEMS structure 102. The cover 114 may be mechanically connected to the side wall portions 106 to provide the cavity 104 hermetically sealed. The cover 114 may be formed for example by a deposition of material. In some embodiments, the cover 114 may include nitride material such as silicon nitride. In some embodiment, the cover 114 may be formed by migration of semiconductor material from the substrate to form the cover 114. In such embodiments, the cover may comprise crystalline semiconductor material. As recognized by a person skilled in the art, one example of a migration process includes the so called Venecia process known to a person skilled in the art.

As shown in FIG. 1B, the support structure 112 extends within the cavity 104 in a vertical direction (z-direction) continuously from a bottom of the cavity to the cover 114. The support structure 112 has an elongated shape in a lateral dimension parallel to a main surface 100A of the MEMS device 100. The support structure 112 has a maximum lateral extension in a first direction (x-axis) parallel to the main surface 100A of the MEMS device 100 and a minimum lateral extension in a second direction (y-axis) parallel to the main surface 100A. As can be seen, the second direction is perpendicular to the first direction. The maximum lateral extension may also be referred to as a length and the minimum lateral extension may also be referred to as a width. The maximum lateral extension is in embodiments significantly greater than the maximum lateral width. The support structure 112 may be mechanically coupled to the cover 114. The support structure 112 is in some embodiments laterally completely surrounded by the side wall portions but spaced apart from the side wall portions. In some embodiments, the support structure 112 includes at least one free-standing structure such as a free-standing wall which mechanically supports in a vertical direction the cover 114. In some embodiment, the support structure 112 is a single element to provide support for the cover inside the cavity 104.

The support structure 112 may have in a top view (perpendicular to the main surface 100A) an elongated shape as shown in FIG. 1A. In some embodiments, the support structure 112 may have in a top view a rectangular shape. The ratio of length to width (e.g. x-extension/y-extension in FIG. 1A) may in some embodiments be greater than 4. In some embodiments, the ratio may be greater than 10. In other embodiments, the ratio may be greater than 50. The length of the support structure 112 may be in embodiments in a range from 1 to 500 μm. The width of the support structure 112 may be in embodiments within a range from 0.5 to 15 μm. The height (extension in z-direction) of the support structure 112 may vary between 3 and 10 μm. The maximum lateral dimension of the support structure 112 may be greater than the maximum vertical dimension of the support structure 112. In some embodiments, the maximum lateral dimension of the support structure 112 may be greater than the maximum vertical dimension by at least a factor 2. In some embodiments, the maximum lateral dimension of the support structure 112 may be at least greater than the maximum vertical dimension by a factor 5. In other embodiments, the maximum lateral dimension of the support structure 112 may be greater than the maximum vertical dimension by at least a factor 10.

The support structure 112 provides in some embodiments an intermediate mechanical support for the cover 114 only in a vertical direction. The support structure 112 has in some embodiments no other function than supporting the cover. The support structure 112 provides in embodiments no mechanical support in lateral directions or has a mechanical connection in lateral directions. The support structure 112 is in embodiments not laterally connected to a MEMS structure such as the MEMS structure 114 and provides no lateral support to structures other than the cover.

The laterally elongated shape of the support structure 112 may for example allow in some embodiments arranging the support structure 112 within an opening of the movable MEMS structure 102 as shown in FIG. 1A. The opening may have for example an elongated shape such as a shape of a slit or an elongated hole. The opening may extend between the two anchor portions 108 as shown in FIG. 1A.

The laterally elongated shape of the support structure 112 may provide support over certain distances in the direction in which the cover needs more support while minimizing the space consumed for the support structure 112 in directions in which the cover 114 needs less or no support. In embodiments, the support structure 112 may be arranged within an opening of the MEMS structure 102 such as a slit-shaped opening shown in FIG. 1A. The support structure 112 may be placed such that the support structure 112 is laterally completely surrounded by the MEMS structure 102. The support structure 112 may be in a spaced apart relation to the MEMS structure 102, e.g. by providing the support structure 112 in an opening of the MEMS structure 102 which is shaped in accordance with the shape of the support structure 102, e.g. by providing the opening and the support structure 112 with similar elongated shapes. Depending on the opening in the MEMS structure 102, the support structure 112 may be surrounded using other forms, for example circular ring-shaped, oval-ring-shaped or other forms. In some embodiments, the shape of the support structure 112 may correspond to the shape of the opening in the MEMS structure 102. For example, the MEMS structure 102 may have a rectangular shaped opening corresponding to a rectangular shaped support structure 112. Skilled person may recognize that a gap between the MEMS structure 102 and the support structure 112 may be chosen sufficiently large in all lateral directions to allow the resonant movement of the MEMS structure 102 without contacting the non-movable support structure 112 during resonating oscillation.

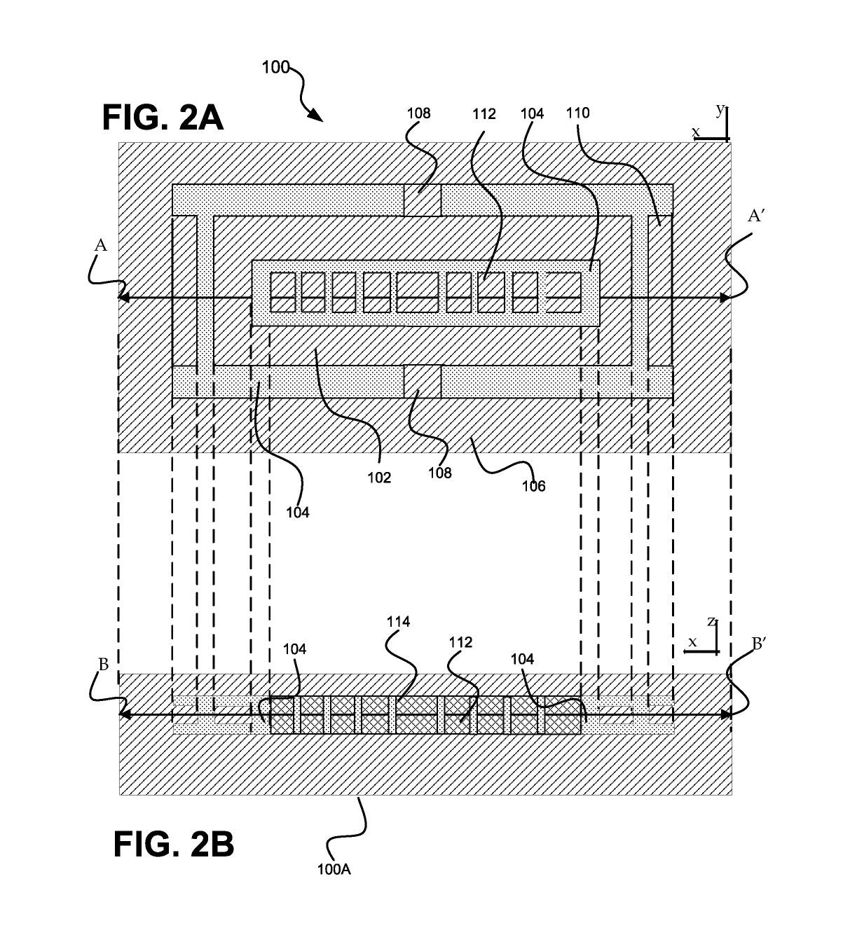

As will be explained below in more detail, the intermediate support structure 112 allows providing the cover 114 thinner. For example, if the MEMS device 102 is provided in the center of the cavity 104, the providing of an opening in the MEMS structure 102 allows arranging the support structure 112 in the center and providing support for the cover 114 at preferred locations. The continuous extension of the support structure 112 in the direction of maximum lateral extension (x-axis in FIG. 1A) provides more support area and more reliability and stability compared for example to non-continuous extending support structures such as a matrix of equally spaced pillars. The cover 112 can be provided thinner which may provide additional manufacturing advantages for example when additional functionality is integrated or provided by the cover 102 such as e.g. electrical through-contacts. However, as will be explained with respect to FIGS. 2A and 2B, in some embodiments, the elongated support structure 112 may be a row of non-continuous support structures instead of a continuously extending support structure 112.

In an example calculation for a nitride cover of square shape, the effect of providing a support structure 112 as a wall extending through a center can be shown. Assuming a thickness of the cover 112 to be h=500 nm, the length and width of the cover to be a=32.5 μm a Young's Modulus to be 153GPA and a Poisson Ratio to be u=0.054 with an air pressure difference (air pressure on outer side of the cover−air pressure on inner side of cover) p=10 kPa, the flexural rigidity D and the center displacement (w1) without support wall and the center displacement (w2) with support wall can be calculated to be

$$D = \frac{E \cdot {h}^{3}}{12 \cdot ( 1 - {v}^{2} )} = \frac{153 GPa \cdot {( 500 nm )}^{3}}{12 \cdot ( 1 - {0.054}^{2} )} \approx 1.6 nNm$$

$$w 1 \approx \frac{p \cdot {a}^{4}}{47 \cdot D} = \frac{10 kPa \cdot {( 32.5 um )}^{4}}{47 \cdot 1.6 nNm} \approx 148 nm$$

$$w 2 \approx \frac{p \cdot {a}^{4}}{47 \cdot D} = \frac{10 kPa \cdot {( 16.25 um )}^{4}}{47 \cdot 1.6 nNm} \approx 9 nm$$

Distances between the MEMS structure 102 and the cover 114 may in some practical applications be in a range between 200 and 400 nm. It can be seen that without the support wall, the minimal distance between the MEMS structure 102 and the cover 114 may be very short and may not allow safe operation of the MEMS structure 102.

The embodiments described above distinguish from a straight forward way to obtain a stable cover for large area MEMS devices by increasing the thickness h of the cover. Embodiments described herein avoid such thick MEMS cover by providing support structures 112 which are arranged intermediate between the side walls 106 which support the cover at the lateral ends. With the reduction of the thickness of the cover, the integration of the MEMS devices in other semiconductor processes is significantly improved. Furthermore electrical contact structures penetrating through the cover can be easier manufactured for thinner covers.

FIG. 2A shows a further embodiment in which recesses are formed in the elongated support structure 112. The recesses structure the support structure 112 in an elongated array provided in one row. As shown in FIGS. 2A and 2B, in some embodiments, specific pieces of the array may be provided with different size, e.g. central pieces or end pieces of the array may have different size than other pieces of the array. In some embodiments, each piece of the array may be of a same size.

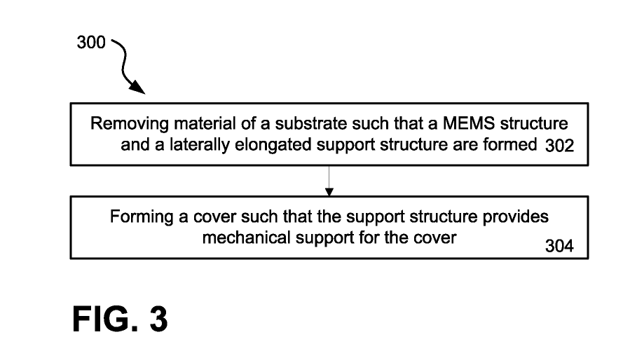

FIG. 3 shows a flow diagram 300 for manufacturing a MEMS device according to an embodiment.

The flow diagram starts at 302 with removing material of a substrate such that a MEMS structure and a laterally elongated support structure (i.e. a support structure having in a topview an elongated shape). At 304 a cover is formed such that the support structure provides mechanical support for the cover.

The removing of material may include for example one etching step or multiple etching steps for forming the MEMS structure and the laterally elongated support structure. The MEMS structure and the laterally elongated support structure may in embodiments be formed concurrently. However in other embodiments, the MEMS structure and the laterally elongated support structure may be formed subsequently. It becomes apparent that between the steps 302 and 304 and after step 304 other manufacturing processes are performed including for example the forming of conductive structures penetrating the cover in order to supply electrical signals to and from the MEMS structure.

In the above description, embodiments have been shown and described herein enabling those skilled in the art in sufficient detail to practice the teachings disclosed herein. Other embodiments may be utilized and derived there from, such that structural and logical substitutions and changes may be made without departing from the scope of this disclosure.

This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon re-viewing the above description.

It is further to be noted that specific terms used in the description and claims may be interpreted in a very broad sense. For example, the terms “circuit” or “circuitry” used herein are to be interpreted in a sense not only including hardware but also software, firmware or any combinations thereof.

It is further to be noted that embodiments described in combination with specific entities may in addition to an implementation in these entity also include one or more implementations in one or more sub-entities or sub-divisions of said described entity.

The accompanying drawings that form a part hereof show by way of illustration, and not of limitation, specific embodiments in which the subject matter may be practiced.

In the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, where each claim may stand on its own as a separate embodiment. While each claim may stand on its own as a separate embodiment, it is to be noted that—although a dependent claim may refer in the claims to a specific combination with one or more other claims—other embodiments may also include a combination of the dependent claim with the subject matter of each other dependent claim. Such combinations are proposed herein unless it is stated that a specific combination is not intended. Furthermore, it is intended to include also features of a claim to any other independent claim even if this claim is not directly made dependent to the independent claim.

Furthermore, it is intended to include in this detailed description also one or more of described features, elements etc. in a reversed or interchanged manner unless otherwise noted.

Further, it is to be understood that the disclosure of multiple steps or functions disclosed in the specification or claims may not be construed as to be within the specific order. Therefore, the disclosure of multiple steps or functions will not limit these to a particular order unless such steps or functions are not interchangeable for technical reasons.

Furthermore, in some embodiments a single step may include or may be broken into multiple sub steps. Such sub steps may be included and part of the disclosure of this single step unless explicitly excluded.

What is claimed is:

1. A MEMS device comprising:
a MEMS structure arranged within a sealed cavity;
a support structure arranged within the cavity, the support structure being laterally elongated and extending in a vertical direction from a bottom of the cavity to a top of the cavity.

2. The MEMS device of claim 1, wherein the support structure has a length in a first lateral direction and a width in a second lateral direction, wherein the ratio of the length to the width is greater than 2.

3. The MEMS device of claim 1, wherein the support structure has a length in a first lateral direction and a width in a second lateral direction, wherein the ratio of the length to the width is greater than 10.

4. The MEMS device of claim 1, further comprising at least one electrode to provide an oscillation of the MEMS structure and at least one sensing structure to sense the oscillation of the MEMS structure.

5. The MEMS device of claim 1, wherein the support structure comprises a freestanding wall, the freestanding wall having a length and a width in a lateral direction and having a height in a vertical direction.

6. The MEMS device of claim 1, wherein the support structure is laterally spaced apart from the MEMS structure and laterally completely surrounded by the MEMS structure.

7. A MEMS device comprising:
a cavity with top, bottom and side walls;
a MEMS structure provided to be movable within the cavity; and
a support structure, wherein the support structure is spaced apart from the MEMS structure and laterally surrounded by the MEMS structure.

8. The MEMS device of claim 7, wherein the MEMS structure is a MEMS structure with an opening, the support structure being arranged within the opening and being spaced apart from the MEMS structure in a lateral direction.

9. The MEMS device of claim 7, wherein the support structure extends from a bottom to a top of the cavity.

10. The MEMS device of claim 7, wherein the support structure is arranged to be rigid with respect to the substrate and wherein the MEMS structure is arranged to be flexible with respect to the substrate.

11. The MEMS device of claim 7, wherein the support structure comprises a laterally elongated shape.

12. The MEMS device of claim 7, wherein the support structure includes at least one freestanding wall connected to a bottom and top of the cavity.

13. The MEMS device of claim 7, wherein the at least one freestanding wall comprise an array of recesses.

14. The MEMS device of claim 7, wherein the cavity has an air pressure substantially lower than an ambient air pressure.

15. A method of manufacturing a MEMS device, the method comprising:
removing material of a substrate such that a MEMS structure and a support structure with a laterally elongated shape are formed; and
forming a cover such that the support structure provides mechanical support for the cover.

16. The method according to claim 15, wherein the forming of the cover comprises a depositing of a cover layer, the cover layer having a mechanical connection to the laterally elongated support structure.

17. The method according to claim 15, wherein the method further comprises:
forming the cover in an evacuated atmosphere.
